(19) United States
(12) Patent Application Publication
(10) Pub. No.: US 2026/0129875 A1
(43) Pub. Date: May 7, 2026

(54) SEMICONDUCTOR PACKAGE

(71) Applicant: Samsung Electronics Co., Ltd., Suwon-si (KR)

(72) Inventor: Hyeonkyu Ha, Suwon-si (KR)

(21) Appl. No.: 19/256,852

(22) Filed: Jul. 1, 2025

(30) Foreign Application Priority Data
Nov. 7, 2024 (KR) 10-2024-0156886

(51) Int. Cl. H01L 23/00; H01L 21/683; H01L 23/31; H01L 23/48; H01L 23/528; H01L 25/18; H05K 1/18; H10B 80/00; H10D 80/30

(52) U.S. Cl. CPC H10B 80/00; H10W 20/20; H10W 20/43; H10W 74/121; H10W 90/00; H05K 1/181; H10D 80/30; H10P 72/74; H10W 80/312; H10W 80/327; H10W 80/334; H10W 90/20; H10W 90/297; H10W 90/792

(57) ABSTRACT

A semiconductor package includes a buffer die, a core die stack on the buffer die, the core die stack including a plurality of core dies stacked in a vertical direction perpendicular to an upper surface of the buffer die, and including a first sidewall, and an adhesive film including a first portion and a second portion, wherein the first portion of the adhesive film is arranged on a lower surface of a top die, the top die being disposed at an uppermost portion of the core die stack, the second portion of the adhesive film extends in a vertical direction and contacts the first sidewall of the core die stack, and the second portion of the adhesive film contacts an upper surface of the buffer die.

### CROSS-REFERENCE TO RELATED APPLICATION

This application is based on and claims priority under 35 U.S.C. § 119 to Korean Patent Application No. 10-2024-0156886, filed on Nov. 7, 2024, in the Korean Intellectual Property Office, the disclosure of which is incorporated by reference herein in its entirety.

### BACKGROUND

Aspects of the inventive concept relate to a semiconductor package. More specifically, aspects of the inventive concept relate to a semiconductor package manufactured through a thermal compression process using a non-conductive film (NCF).

Over the past several decades, advances in technology, materials, and manufacturing processes have led to rapid advances in computing power and wireless communications technology. This has enabled implementation of high-integration and high-performance transistors, and the speed of integration has doubled approximately every 18 months according to Moore's law. Miniaturization and power efficiency of systems are the ongoing goals of semiconductor manufacturing, and at this point, when the economic and physical process limits are being reached, 3D integrated packaging is presented as an effective solution.

### SUMMARY

Aspects of the inventive concept provide a semiconductor package with improved reliability and performance.

The objective to be solved by the application is not limited to the objectives above, and other objectives will be clearly understood by those skilled in the art from the description below.

In order to achieve the technical problem, aspects of the inventive concept provide a semiconductor package as below.

According to an aspect of the inventive concept, there is provided a semiconductor package including a buffer die, a core die stack on the buffer die, the core die stack including a plurality of core dies stacked in a vertical direction perpendicular to an upper surface of the buffer die, and including a first sidewall, and an adhesive film including a first portion and a second portion, wherein the first portion of the adhesive film is arranged on a lower surface of a top die, the top die being disposed at an uppermost portion of the core die stack, the second portion of the adhesive film extends in a vertical direction and contacts the first sidewall of the core die stack, and the second portion of the adhesive film contacts an upper surface of the buffer die.

According to another aspect of the inventive concept, there is provided a semiconductor package including a buffer die, a core die stack on the buffer die, the core die stack including first dies stacked in a vertical direction perpendicular to an upper surface of the buffer die to form a stacked structure, and a second die disposed on the stacked structure, a horizontal portion of an adhesive film, which bonds a top first die, positioned at an uppermost portion of the stacked structure among the first dies, to the second die, a fillet portion of the adhesive film, the fillet portion extends along the sidewall of the core die stack toward the upper surface of the buffer die, wherein a first end of the fillet portion is integrally connected to the horizontal portion of the adhesive film, and a second end of the fillet portion, opposite to the first end, is in contact with the upper surface of the buffer die, and a molding layer that covers a top surface of the buffer die and surrounds the core die stack, the horizontal portion of the adhesive film, and the fillet portion of the adhesive film, wherein all bonding between the first dies is by a direct bonding process.

According to another aspect of the inventive concept, there is provided a semiconductor package including a buffer die, core dies disposed on the buffer die and hybrid bonded to each other, a dummy die arranged on the core dies, an adhesive film between the core dies and the dummy die, a fillet connected to an end of the adhesive film and that extends vertically downward along sidewalls of the core and contacts the buffer die, and a molding layer that covers a top surface of the buffer die and surrounds the core dies, the dummy die, the adhesive film, and the fillet, wherein the dummy die is bonded to the core dies by a thermal compression process, the fillet is a portion of the adhesive film, which has melted and is hardened through the thermal compression process, each of the core dies includes a semiconductor substrate, an internal circuit region disposed under the semiconductor substrate, a back protective layer disposed on the semiconductor substrate, and a through electrode structure that extends through the back protective layer and the semiconductor substrate into the internal circuit region, and a core die positioned at a lowermost portion among the core dies, the buffer die, and the fillet are connected to each other.

### BRIEF DESCRIPTION OF THE DRAWINGS

Embodiments will be more clearly understood from the following detailed description taken in conjunction with the accompanying drawings in which:

FIG. 1 is a layout diagram for describing a semiconductor package according to some embodiments;

FIG. 2 is a cross-sectional view taken along line A-A′ of FIG. 1;

FIG. 3 is an enlarged cross-sectional view of region EX1 of FIG. 2;

FIG. 4 is a cross-sectional view of a semiconductor package according to some embodiments;

FIG. 5 is a cross-sectional view of a semiconductor package according to some embodiments; and

FIGS. 6A to 6C are cross-sectional views illustrating parts of a manufacturing method of an embodiment, to explain a semiconductor package according to some embodiments.

### DETAILED DESCRIPTION OF THE EMBODIMENTS

Hereinafter, embodiments will be described in detail with reference to the attached drawings. The same reference numerals are used for identical components in the drawings, and repeated descriptions of these are omitted.

Items described in the singular herein may be provided in plural, as can be seen, for example, in the drawings. Thus, the description of a single item that is provided in plural in the drawings should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

As aspects of the inventive concept allow for various changes and many different forms, particular embodiments will be illustrated in the drawings and described in detail in the written description. However, this is not intended to limit the scope to specific embodiments, but should be understood to include all transformations, equivalents, or alternatives included in the scope of the disclosed ideas and techniques. In describing the embodiments, if it is determined that a detailed description of a related known technology may obscure the gist, the detailed description is omitted.

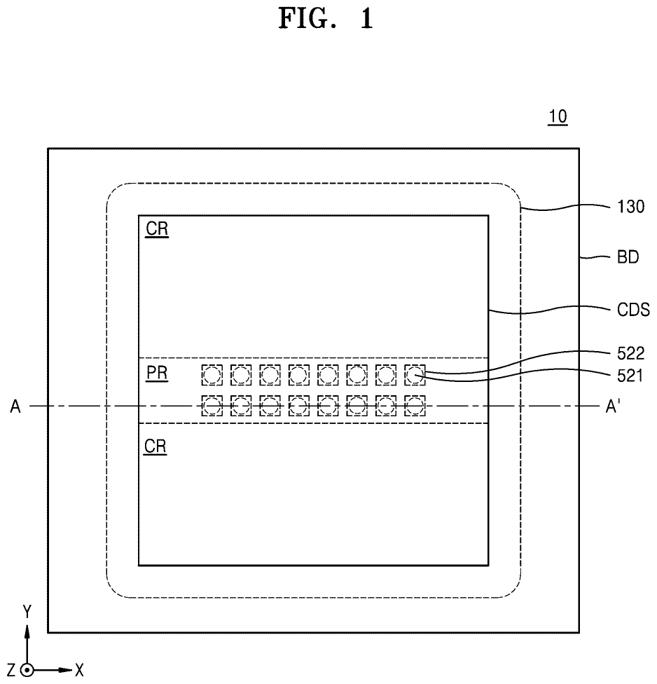

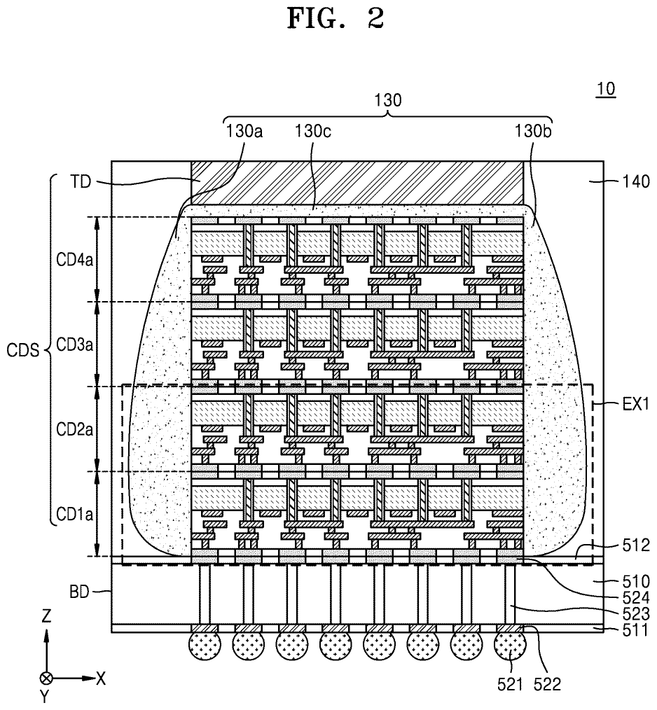

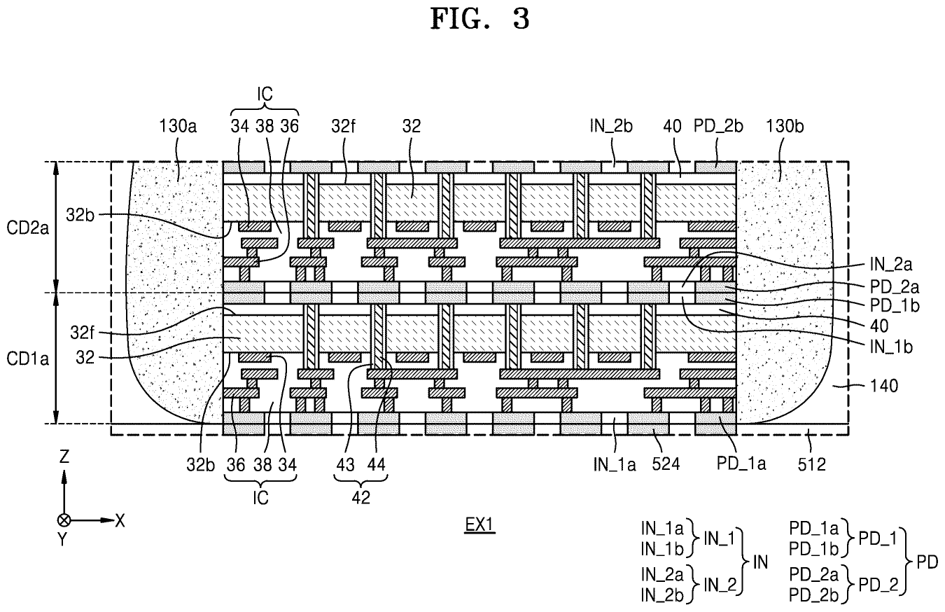

FIG. 1 is a layout diagram for describing a semiconductor package 10 according to some embodiments. FIG. 2 is a cross-sectional view taken along line A-A′ of FIG. 1; FIG. 3 is an enlarged cross-sectional view of region EX1 of FIG. 2.

Referring to FIGS. 1, 2, and 3, the semiconductor package 10 may include a buffer die BD, a core die stack CDS, an adhesive film 130, and a molding layer 140. According to some embodiments, the semiconductor package 10 illustrated in FIGS. 1, 2, and 3 may be a high bandwidth memory (HBM) including a plurality of dynamic random access memory (DRAM) chips and logic chips.

The semiconductor package 10 may include a circuit region CR where a circuit is formed and a pad region PR for electrical connection between a plurality of core dies (e.g., CD1a, CD2a, CD3a, CD4a) stacked in a vertical direction and included in the core die stack CDS. Although two circuit regions CR spaced apart from each other with the pad region PR therebetween is illustrated in FIG. 1, this is for illustrative purposes only and does not limit aspects of the inventive concept in any way. A horizontal cross-sectional area of the buffer die BD may be greater than a horizontal cross-sectional area of the core die stack CDS.

The pad region PR may be a region where a plurality of buffer through electrodes 523, a plurality of buffer lower pads 522, a plurality of buffer upper pads 524, a plurality of buffer lower solders 521, a plurality of through electrode structures 42, and a plurality of bonding pads PD are arranged.

The plurality of buffer through electrodes 523, the plurality of buffer lower pads 522, the plurality of buffer upper pads 524, the plurality of buffer lower solders 521, the plurality of through electrode structures 42, and the plurality of bonding pads PD may be arranged in various layouts in a first horizontal direction (X direction) and a second horizontal direction (Y direction) within the pad region PR. According to some embodiments, as illustrated in FIG. 1, a plurality of pads and a plurality of solders in the pad region PR may form a matrix with a certain pitch in the first horizontal direction (X direction) and the second horizontal direction (Y direction). Although not shown, the above may also apply to a plurality of through electrodes. Referring to FIG. 1, when viewed from above, the planar shape of the plurality of buffer lower solders 521 is depicted as being approximately circular, but is not limited thereto. For example, the planar shape of the plurality of buffer lower solders 521 may be rectangular.

In addition, for convenience of illustration, FIGS. 1 and 2 illustrate eight buffer through electrodes 523 arranged in the first horizontal direction (X direction) within the pad region PR, and six through electrode structures 42 arranged in the first horizontal direction (X direction). However, the number and arrangement of the buffer through electrodes 523 and the through electrode structures 42 are not limited to those illustrated in FIGS. 1 and 2.

In some embodiments, the buffer die BD may include a logic chip. Here, the logic chip may be any one of a gate array, a cell-based array, an embedded array, a structured application-specific integrated circuit (ASIC), a field programmable gate array (FPGA), a complex programmable logic device (CPLD), a central processing unit (CPU), a micro processing unit (MPU), a micro controller unit (MCU), a logic integrated chip (IC), an application processor (AP), a driver driving IC, a radio frequency (RF) chip, and a complementary metal oxide semiconductor (CMOS) image sensor. However, aspects of the inventive concept are not limited thereto, and the buffer die BD may include a memory chip.

The buffer die BD may include a buffer substrate 510, a buffer lower insulating film 511, the buffer lower solders 521, the buffer lower pads 522, a buffer upper insulating film 512, the buffer upper pads 524, and the buffer through electrodes 523.

In some embodiments, the buffer substrate 510 may include silicon (Si). Alternatively, the buffer substrate 510 may include a semiconductor element such as germanium (Ge), or a compound semiconductor such as silicon carbide (SiC), gallium arsenide (GaAs), indium arsenide (InAs), and indium phosphide (InP). Alternatively, the buffer substrate 510 may have a silicon on insulator (SOI) structure. For example, the buffer substrate 510 may include a buried oxide (BOX) layer. The buffer substrate 510 may include a conductive region, for example, a doped well, or a doped structure. Additionally, the buffer substrate 510 may have various element isolation structures such as a shallow trench isolation (STI) structure.

In some embodiments, the buffer substrate 510 may include a plurality of individual devices of various types and an interlayer insulating film. The plurality of individual devices may include various microelectronic devices, for example, metal-oxide-semiconductor field effect transistors (MOSFETs) such as CMOS transistors, system large scale integration (LSI), flash memory, DRAM, static random access memory (SRAM), electrically erasable programmable read-only memory (EEPROM), phase-change random access memory (PRAM), magnetoresistive random access memory (MRAM), or resistance random access memory (RERAM), image sensors such as CMOS imaging sensors (CIS), micro-electro-mechanical systems (MEMS), active elements, passive elements, etc. The plurality of individual devices may be formed within the buffer substrate 510 in the circuit region CR, and the plurality of individual devices may be electrically connected to the conductive region of the buffer substrate 510. The buffer substrate 510 may further include a conductive wire or a conductive plug electrically connecting at least two of the plurality of individual devices to each other or the plurality of individual devices to the conductive region of the buffer substrate 510. Additionally, each of the plurality of individual devices may be electrically isolated from neighboring individual devices by insulating films.

In some embodiments, the buffer substrate 510 may be formed to include a plurality of wiring structures for connecting the plurality of individual devices to other wirings formed on the buffer substrate 510. The plurality of wiring structures may include metal wiring patterns extending in a horizontal direction and via plugs extending in a vertical direction. The metal wiring patterns and the via plugs may include a barrier film and a conductive layer. The barrier film for wiring may include at least one material selected from titanium (Ti), titanium nitride (TiN), tantalum (Ta), and tantalum nitride (TaN). The conductive layer may include at least one metal selected from tungsten (W), aluminum (Al), and copper (Cu). The plurality of wiring structures may be a multilayer structure in which two or more metal wiring patterns and two or more via plugs are alternately stacked. According to some embodiments, the buffer lower pads 522 and the buffer upper pads 524 may also include at least one metal selected from tungsten (W), aluminum (Al), and copper (Cu).

In some embodiments, the buffer substrate 510 may have a lower surface and an upper surface facing each other, and the buffer lower insulating film 511 may be disposed on the lower surface of the buffer substrate 510, and the buffer upper insulating film 512 may be disposed on the upper surface of the buffer substrate 510. In the present specification, a lower surface and an upper surface of a substrate indicates surfaces perpendicular to a direction in which the substrate is stacked (i.e., a vertical direction, a Z direction), and in particular, the lower surface may indicate a surface with a relatively low vertical level, and the upper surface may indicate a surface with a relatively high vertical level. The buffer lower insulating film 511 and the buffer upper insulating film 512 may include protective layers to protect the buffer substrate 510 and the wiring structure formed therein, from external impact or moisture. In some embodiments, the buffer lower insulating film 511 and the buffer upper insulating film 512 may include at least one of silicon nitride, silicon oxide, and silicon oxynitride.

In some embodiments, the buffer lower solders 521 and the buffer lower pads 522 may be disposed on the lower surface of the buffer substrate 510. The buffer lower solders 521 and the buffer lower pads 522 may form a stacked structure. A side surface of the buffer lower pads 522 may be covered by the buffer lower insulating film 511. One surface of the buffer lower pads 522 may be exposed to the outside (e.g., not covered by the buffer lower insulating film 511) and form a coplanar surface with an upper surface of the buffer lower insulating film 511.

In some embodiments, the buffer lower solders 521 may be arranged on the buffer lower pads 522 to electrically connect the buffer die BD to an external device. The buffer lower solders 521 may be arranged on the buffer substrate 510 and come into contact with the buffer lower pads 522. The buffer lower solders 521 may include at least one of tin (Sn), titanium (Ti), vanadium (V), antimony (Sb), lead (Pb), tungsten (W), chromium (Cr), copper (Cu), nickel (Ni), aluminum (Al), palladium (PD), silver (Ag), and gold (Au).

In some embodiments, the buffer lower solders 521 may include a single metal layer or a stacked structure of a plurality of metal layers. For example, the buffer lower solders 521 may include a first metal layer, a second metal layer, and a third metal layer sequentially stacked. The first metal layer may include a material having excellent adhesion to the buffer lower pads 522 and the buffer lower insulating film 511. For example, the first metal layer may be an adhesive layer for improving the stability of the formation of the buffer lower solders 521. The first metal layer may include, for example, at least one of titanium (Ti), titanium-tungsten (Ti—W), chromium (Cr), and aluminum (Al). The second metal layer may be a barrier layer that prevents a metal material included in the buffer lower solders 521, from diffusing into the buffer substrate 510. The second metal layer may include at least one of copper (Cu), nickel (Ni), chromium-copper (Cr—Cu), and nickel-vanadium (Ni—V). The third metal layer may act as a seed layer for forming the buffer lower solders 521 or a wetting layer for improving the wetting characteristics of the buffer lower solders 521. The third metal layer may include at least one of nickel (Ni), copper (Cu), and aluminum (Al).

The buffer lower solders 521 may form a lowest surface of the semiconductor package 10. In some embodiments, the buffer lower solders 521 may include chip-substrate connection solders for mounting the semiconductor package 10 on an external substrate or interposer. In some other embodiments, the buffer lower solders 521 may include chip-chip connection solders for mounting the semiconductor package 10 on an external substrate or interposer.

The buffer lower solders 521 may include a solder material. The buffer lower solders 521 may include tin (Sn), indium (In), bismuth (Bi), antimony (Sb), copper (Cu), silver (Ag), zinc (Zn), lead (Pb) and/or alloys thereof. For example, the buffer lower solders 521 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and the like.

In some embodiments, the buffer upper pads 524 may be disposed on the upper surface of the buffer substrate 510. A side surface of the buffer upper pads 524 may be covered by the buffer upper insulating film 512. One surface of the buffer upper pads 524 may be exposed to the outside and form a coplanar surface with an upper surface of the buffer upper insulating film 512. A core bottom solder 121 may be arranged on the buffer upper pads 524 to electrically connect the buffer die BD to the core die stack CDS.

In some embodiments, the buffer through electrodes 523 may be disposed within the buffer substrate 510 and configured to penetrate the buffer substrate 510 and be electrically connected to the buffer lower solders 521, the buffer lower pads 522, and the buffer upper pads 524. The buffer through electrodes 523 may penetrate the buffer substrate 510 in the vertical direction (Z direction). The buffer through electrodes 523 may electrically connect the core die stack CDS to an external device by electrically connecting the buffer upper pads 524 to the buffer lower solders 521 and the buffer lower pads 522.

In some embodiments, the buffer through electrodes 523 may have a pillar shape. The buffer through electrodes 523 may include a barrier film defining a columnar surface and a buried conductive layer filling the interior of the barrier film. The barrier film may include, for example, at least one of titanium (Ti), titanium nitride (TiN), tantalum (Ta), or tantalum nitride (TaN), ruthenium (Ru), cobalt (Co), manganese (Mn), tungsten nitride (WN), nickel (Ni), and nickel boronide (NiB), and the buried conductive layer may include at least one of Cu or a Cu alloy such as CuSn, CuMg, CuNi, CuZn, CuPd, CuAu, CuRe, CuW, W, a W alloy, Ni, Ru, and Co. In some embodiments, the buffer through electrodes 523 may be formed at the same level as the buffer substrate 510 and may further include a through-via insulating film covering the barrier film. The through-via insulating film may include an oxide film, a nitride film, a carbide film, a polymer, or a combination thereof.

In some embodiments, the plurality of core dies CD (e.g., CD1a-CD4a) may include, for example, memory semiconductor chips. Examples of the memory semiconductor chips may include a volatile memory semiconductor chip such as DRAM or SRAM, or a nonvolatile memory semiconductor chip such as PRAM, MRAM, ferroelectric random access memory (FeRAM), or ReRAM. According to some embodiments, each of the plurality of core dies CD may include a DRAM semiconductor chip for forming an HBM.

In FIG. 2, the semiconductor package 10 in which four core dies, that is, first to fourth core dies CD1a, CD2a, CD3a, and CD4a, and one dummy die TD are stacked is illustrated as an example, but the number of semiconductor chips stacked in the semiconductor package 10 is not limited thereto. For example, 2 to 32 semiconductor chips may be stacked within the semiconductor package 10. Dummy die TD may have the same or similar structure and shape as each of the plurality of core dies CD, but does not have a substantial function. For example, dummy die TD may not perform a data storage function or a data processing function. For example, the dummy die TD may not have any transistors. In some examples, the dummy die TD may be a bulk semiconductor substrate, such as a bulk crystalline silicon substrate. In certain instances, the dummy die TD may referred to as the uppermost die of the core die stack CDS or as the top die of the core die stack CDS.

In some embodiments, the first to fourth core dies CD1a, CD2a, CD3a, and CD4a may be arranged on the buffer die BD.

Referring to FIG. 3, the first core die CD1a may include a semiconductor substrate 32, an internal circuit region IC disposed under the semiconductor substrate 32, and a back protective layer 40 disposed on the semiconductor substrate 32. In embodiments, the structures of the second to fourth core dies CD2a, CD3a, and CD4a may be identical to that of the first core die CD1a, and thus may be referred to together with the description of the first core die CD1a.

In embodiments, the first core die CD1a may further include the through electrode structure 42 that penetrates the back protective layer 40 and the semiconductor substrate 32 and extends into the internal circuit region IC. In embodiments, the through electrode structure 42 may include a through electrode 44, which is conductive, and an insulating through-spacer 43 covering a side surface of the through electrode 44. In embodiments, the internal circuit region IC may include an internal circuit 34, connection wires 36 electrically connected to the internal circuit 34, and a body 38 covering the internal circuit 34 and the connection wires 36.

In some embodiments, the semiconductor substrate 32 may have a front surface 32b and a back surface 32f that face each other. In the first core die CD1a, the internal circuit region IC may be arranged under the front surface 32b of the semiconductor substrate 32, and the back protective layer 40 may be arranged on the back surface 32f of the semiconductor substrate 32.

In some embodiments, the semiconductor substrate 32 may include silicon (Si). Alternatively, the semiconductor substrate 32 may include a semiconductor element such as germanium (Ge), or a compound semiconductor such as silicon carbide (SiC), gallium arsenide (GaAs), indium arsenide (InAs), and indium phosphide (InP). Alternatively, the semiconductor substrate 32 may have an SOI structure. Additionally, each of the core dies CD1a, CD2a, CD3a, CD4a may have various device isolation structures, such as an STI structure.

If the semiconductor chips include memory chips, the internal circuit 34 may include a memory cell array and peripheral circuits. If the semiconductor chips are DRAM chips, the memory cell array may include DRAM memory cells, for example, cell switching elements and DRAM capacitors. If the semiconductor chips include NAND flash memory chips, the memory cell array may include memory cell transistors. The semiconductor chips in the embodiments are not limited to the DRAM chips or NAND flash memory chips described above, and may include other memory chips or logic chips.

In the present specification, the terms ‘first bonding pad, second bonding pad, first bonding insulating layer, and second bonding insulating layer’ may refer to pads and insulating layers used in a first bonding process. For example, the first bonding process may include a hybrid bonding process. Here, the hybrid bonding process may include a direct bonding process in which metals are directly bonded to each other (and merge together) and insulating layers are directly bonded to each other (and merge together).

Referring again to FIG. 3, the first core die CD1a may include a first lower bonding pad PD_1a and a first lower bonding insulating layer IN_1a disposed below the front surface 32b of the semiconductor substrate 32, and a first upper bonding pad PD_1b and a first upper bonding insulating layer IN_1b disposed above the back surface 32f of the semiconductor substrate 32.

Similarly, the second core die CD2a may include a second lower bonding pad PD_2a and a second lower bonding insulating layer IN_2a disposed below the front surface 32b of the semiconductor substrate 32, and a second upper bonding pad PD_2b and a second upper bonding insulating layer IN_2b disposed above the back surface 32f of the semiconductor substrate 32.

Although the third core die CD3a and the fourth core die CD4a are not illustrated in FIG. 3, it may be understood with reference to FIG. 2 that the third core die CD3a and the fourth core die CD4a may also have the same structure as the first and second core dies CD1a and CD2a.

A first bonding insulating layer IN_1 and a second bonding insulating layer IN_2 may include silicon oxide. However, the embodiments are not limited thereto. For example, the first and second bonding insulating layers IN_1 and IN_2 may include an insulating material such as silicon carbon nitride (SiCN).

In embodiments, the first lower bonding pad PD_1a and the second lower bonding pad PD_2a may have the same thickness. In embodiments, the first upper bonding pad PD_1b and the second upper bonding pad PD_2b may have the same thickness. In some embodiments, the first bonding pad PD_1 and the second bonding pad PD_2 may have the same thickness, but aspects of the inventive concept are not limited thereto.

In embodiments, the through electrode structure 42 may be configured to penetrate the semiconductor substrate 32 within the first core die CD1a and electrically connect the internal circuit region IC to the first upper bonding pad PD_1b. The through electrode structure 42 may penetrate the semiconductor substrate 32 in the vertical direction (Z direction). The through electrode structure 42 may electrically connect the core die CD to another core die CD, and the core die CD to the buffer die BD and/or an external device.

Referring to FIG. 2, the semiconductor package 10 may include the adhesive film 130 that bonds the core die stack CDS. The adhesive film 130 may include a horizontal portion 130c, a first fillet 130a, and a second fillet 130b. The horizontal portion 130c of the adhesive film 130 may be referred to as a first portion of the adhesive film 130. In some instances, the first fillet 130a and the second fillet 130b may be each individually referred to as a second portion of the adhesive film 130. In some instances, the first fillet 130a and the second fillet 130b may be collectively referred to as a second portion of the adhesive film 130. In some instances, the first fillet 130a and the second fillet 130b (i.e., the fillets visible in a cross-sectional view along the X direction) and the two fillets, although not visible in FIG. 2 but visible in a cross-sectional view along the Y direction, may be collectively referred to as a second portion of the adhesive film 130. In some embodiments, the horizontal portion 130c of the adhesive film 130 is disposed between the fourth core die CD4a and the dummy die TD (e.g., uppermost die, top die) may extend in a horizontal direction, i.e., in the first horizontal direction (X direction) and the second horizontal direction (Y direction). The first fillet 130a and the second fillet 130b may be a result of a portion of the horizontal portion 130c of the adhesive film 130, the portion having flowed down and being hardened through a thermal compression process, as will be described later. An adhesive film may not be formed between respective core dies of the core die stack CDS. For example, the horizontal portion 130c of the adhesive film 130 is not formed between vertically adjacent core dies of the core die stack CDS.

In FIG. 2, the first fillet 130a and the second fillet 130b that are mirror-symmetrically spaced apart from each other to the left and right, respectively, with respect to the core die stack CDS, are illustrated, but this is depicted only in this way because FIG. 2 is a cross-sectional view taken along the line A-A′ of FIG. 1, and fillets formed by the portion of the horizontal portion 130c, flowing out from the horizontal portion 130c, may be formed as a single body, wrapping the core die stack CDS in all directions. For example, the horizontal portion 130c of the adhesive film 130 may flow out from between the uppermost core die in the core die stack CDS (e.g., the fourth core die CD4a) and the dummy die TD, such that the adhesive film 130 extends beyond an edge of the uppermost core die and an edge of the dummy die TD in a horizontal direction and extends in the vertical direction contacting sides of the core die stack CDS and contacting an upper surface of the buffer die BD to thereby form the first fillet 130a. As illustrated, for example, in the cross-section view of FIG. 2, the height of the first fillet 130a may be greater than the height of the core die stack CDS in the vertical direction. The height of the first fillet 130a may be substantially the same as the height of the second fillet 130b. The dummy die TD may not overlap the first fillet 130a and the second fille 130b in the vertical direction. The first fillet 130a and the second fillet 130b may be formed substantially as a single body and simultaneously.

As illustrated, for example, with respect to the cross-section view of FIG. 2, the width of the first fillet 130a in the first horizontal direction (X direction) may vary along the vertical direction (Z direction). A first end of the first fillet 130a, which is in contact with the horizontal portion 130c of the adhesive film 130, may have a first width in the first horizontal direction. A second end of the first fillet 130a, which is in contact with the buffer die BD, may have a second width in the first horizontal direction. The first width may be less than the second width. Between the first end of the first fillet 130a and the second end of the first fillet 130a, the first fillet 130a may have a third width in the first horizontal direction. The third width may be the maximum width of the first fillet 130a. For example, the third width is greater than the first width and the second width. The widths (e.g., the first width, the second width, and the third width) of the first fillet 130a may be substantially the same as the widths of the second fillet 130b.

As further illustrated, for example, with respect to the cross-section view of FIG. 2, the outer surface of the first fillet 130a may form a smooth curve along its entire length having a single point of maximum extension with respect to its extension in the horizontal direction (e.g., with respect to a vertical cross-section, the portion of the fillet 130a that is farthest from the core die stack CDS in the horizontal direction is point on a convex surface of the fillet). The single point of maximum of the smooth curve may be adjacent to the lowermost core die in the core die stack CDS (e.g., the first core die CD1a). The shape of the first fillet 130a may be substantially the same as the widths of the second fillet 130b.

First fillet 130a and the second fillet 130b are formed on respective sides of the core die stack CDS in the X direction. Third and fourth fillets (not shown in the cross-section views of FIGS. 2 and 3) may be formed on respective sides of the core die stack CDS in the Y direction. The third and fourth fillets may be identical to the first fillet 130a and the second fillet 130b described herein (including this embodiment and other embodiments), including having the same shape, structure and physical relationships as described with respect to the first fillet 130a and the second fillet 130b (of this embodiment and other embodiments) and the core die stack CDS. Adjacent ones of the first, second, third and fourth fillets may connect together/merge (at respective corners of the core die stack CDS) and form a single continuous homogenous body that surrounds the core die stack (CDS) with respect to a top down view. The adhesive film 130 may have the form of an inverted cup in which the core die stack (CDS) is positioned, including the first to fourth interconnected fillets that form sides of the cup and that merge with the horizontal portion 130c of the adhesive film 130 that forms the bottom of the inverted cup.

The adhesive film 130 may be an adhesive film for bonding the fourth core die CD4a to the dummy die TD, and the core die stack CDS to the buffer die BD. The fourth core die CD4a and the dummy die TD may be bonded to each other by a thermal compression process using the adhesive film 130. By the thermal compression process, a portion of the adhesive film 130 may flow out, and the horizontal portion 130c of the adhesive film 130 may remain in a portion where the adhesive film 130 was arranged, and the other portions of the adhesive film 130, which are melted by heat, that is, the first and second fillets 130a and 130b, may flow out. The thermal compression process may be performed until the first and second fillets 130a and 130b flow down a sidewall of the core die stack CDS and contact the buffer die BD, the first and second fillets 130a and 130b are subsequently hardened and partially contracted to hold a space between the core die stack CDS and the buffer die BD, thereby reducing the risk of delamination between the buffer die BD and the core die stack CDS and thus improving the device stability and reliability.

As illustrated in FIG. 2, the adhesive film 130 may include a portion that contacts an upper surface of the buffer die BD between the first core die CD1a located at the lowermost position of the core die stack CDS and the buffer die BD.

The adhesive film 130 may be an insulating material. The adhesive film 130 may include, for example, an NCF film. The adhesive film 130 may be a polymer material. The adhesive film 130 may include, for example, epoxy, a hardener, a polymer, a flux, and/or a filler.

In some embodiments, the semiconductor package 10 may include the molding layer 140 surrounding the core die stack CDS. The molding layer 140 may surround the core die stack CDS and the adhesive film 130 covering at least a portion of the sidewall of the core die stack CDS. The molding layer 140 may mold the core die stack CDS and the buffer die BD together. The molding layer 140 may be, for example, epoxy mold compound (EMC) and include resin.

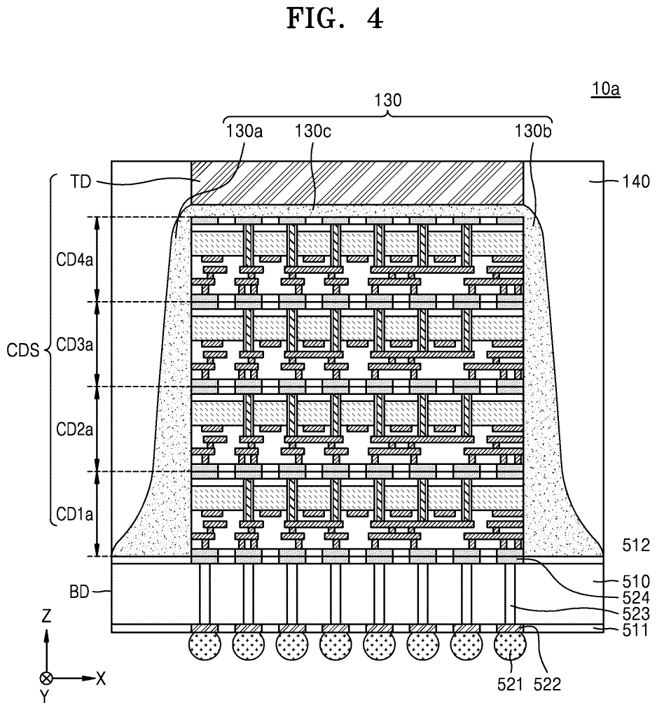

FIG. 4 is a cross-sectional view of a semiconductor package 10a according to some embodiments.

The semiconductor package 10a of FIG. 4 may be the same as the semiconductor package 10 described with reference to FIGS. 2 and 3, except that the shape of the first and second fillets 130a and 130b is different, and the remaining components may be the same as described above. Since the first and second fillets 130a and 130b are portions of the adhesive film 130 and are a result of the horizontal portion 130c of the adhesive film, which has flowed out and is hardened, the shape of the first and second fillets 130a and 130b may be as shown in FIG. 4. For example, the horizontal portion 130c of the adhesive film 130 may flow out from between the uppermost core die in the core die stack CDS (e.g., the fourth core die CD4a) and the dummy die TD, such that the adhesive film 130 extends beyond an edge of the uppermost core die and an edge of the dummy die TD in a horizontal direction and extends in the vertical direction contacting sides of the core die stack CDS and contacting an upper surface of the buffer die BD to thereby form the first fillet 130a. As illustrated, for example, in the cross-section view of FIG. 4, the height of the first fillet 130a may be greater than the height of the core die stack CDS in the vertical direction. The height of the first fillet 130a may be substantially the same as the height of the second fillet 130b. The dummy die TD may not overlap the first fillet 130a and the second fille 130b in the vertical direction.

As illustrated, for example, in the cross-section view of FIG. 4, the width of the first fillet 130a in the first horizontal direction (X direction) may vary along the vertical direction (Z direction). For example, the width of the first fillet 130a may increase along the length of the first fillet 130a in the vertical direction. A first end of the first fillet 130a, which is in contact with the horizontal portion 130c of the adhesive film 130, may have a first width in the first horizontal direction. A second end of the first fillet 130a, which is in contact with the buffer die BD, may have a second width in the first horizontal direction. The first width may be less than the second width. Between the first end of the first fillet 130a and the second end of the first fillet 130a, the first fillet 130a may have a third width in the first horizontal direction. The third width may be greater than the first width and less than the second width. The second width may be the maximum width of the first fillet 130a. The widths (e.g., the first width, the second width, and the third width) of the first fillet 130a may be substantially the same as the widths of the second fillet 130b.

As further illustrated, for example, in the cross-section view of FIG. 4, the outer surface of the first fillet 130a may form a smooth curve having a single point of maximum extension. The single point of maximum extension of the smooth curve may be adjacent to the lowermost core die in the core die stack CDS (e.g., the first core die CD1a). The shape of the first fillet 130a may be substantially the same as the widths of the second fillet 130b.

The shape of the first and second fillets 130a and 130b may have a different shape than that shown in FIGS. 3 and 4. The shape of the first and second fillets 130a and 130b is not limited to that illustrated in the drawings, provided that at least a portion thereof is in contact with the upper surface of the buffer die BD.

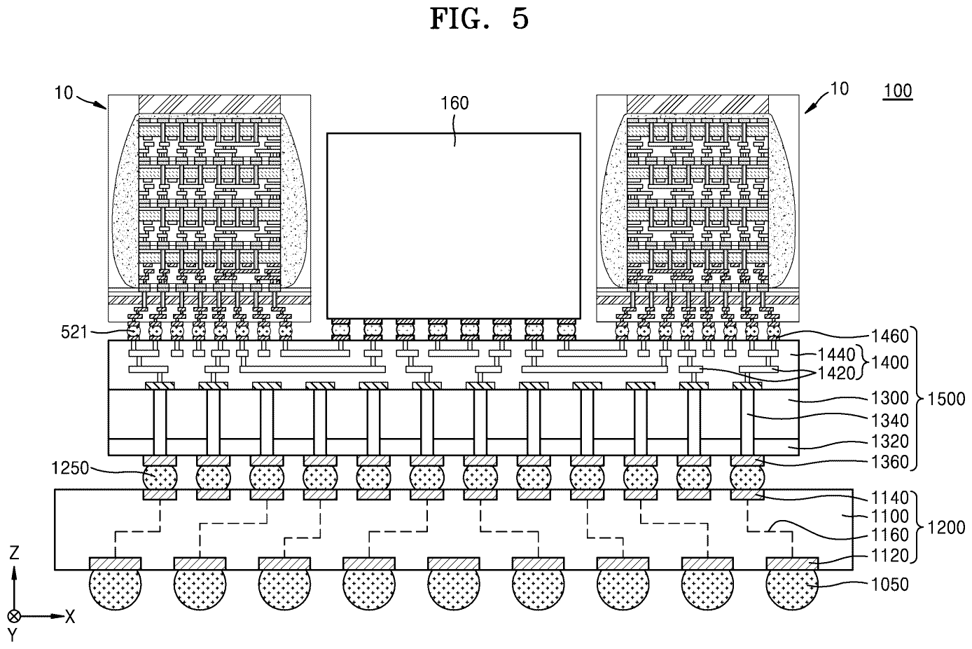

Next, an embodiment of a semiconductor package 100 including one of the semiconductor packages 10 and 10a described with reference to FIGS. 1 to 4 will be described with reference to FIG. 5. FIG. 5 is a cross-sectional view conceptually illustrating an embodiment of the semiconductor package 100 including one of the semiconductor packages 10 and 10a described with reference to FIGS. 1 to 4.

Referring to FIG. 5, the semiconductor package 100 according to an embodiment may include a package substrate 1200, an interposer 1500, and the semiconductor package 10 and a semiconductor chip 160 mounted on the interposer 1500. In FIG. 5, the semiconductor package 100 is illustrated as the semiconductor package 10 described with reference to FIGS. 1 to 3, but the embodiment is not limited thereto. For example, the semiconductor package 10 may be replaced with the semiconductor package 10a described with reference to FIG. 4. The semiconductor chip 160 may include a processor chip.

In embodiments, the package substrate 1200 may include a substrate for a semiconductor package, including a printed circuit board PCB, a ceramic substrate, a glass substrate, a tape wiring board, and the like. The package substrate 1200 may include a body 1100, a lower pad 1120 disposed on a lower surface of the body 1100, an upper pad 1140 disposed on an upper surface of the body 1100, and a wiring circuit 1160 electrically connecting the lower pad 1120 to the upper pad 1140 within the body 1100.

In embodiments, the body 1100 of the package substrate 1200 may include different materials depending on the type of substrate. For example, if the package substrate 1200 is a printed circuit board, the package substrate 1200 may be in the form of a body copper-clad laminate or a wiring layer additionally stacked on one side or both sides of a copper-clad laminate.

In embodiments, the lower pad 1120, the upper pad 1140, and the wiring circuit 1160 may form a signal path. An external connection bump 1050 connected to the lower pad 1120 may be arranged under a lower surface of the package substrate 1200. The external connection bump 1050 may include, for example, a solder ball.

In embodiments, the interposer 1500 may include a substrate 1300, a lower protective layer 1320, a lower pad 1360, an interconnection structure 1400, and a through via 1340. The semiconductor package 10 and the semiconductor chip 160 may be stacked on the package substrate 1200 via the interposer 1500.

The interposer 1500 may electrically connect the semiconductor package 10 and the semiconductor chip 160 to each other. For example, a portion of the interconnection structure 1400 of the interposer 1500 may provide a signal path through which the semiconductor package 10 and a semiconductor chip 160 may communicate or be electrically connected with each other.

In embodiments, the substrate 1300 may include, for example, any one of a silicon, organic, plastic, and glass substrate. When the substrate 1300 includes a silicon substrate, the substrate 1300 may be referred to as a silicon interposer. Unlike the illustration in the diagram, if the substrate 1300 includes an organic substrate, the substrate 1300 may be referred to as a panel interposer.

The lower protective layer 1320 may be arranged under a lower surface of the substrate 1300, and the lower pad 1360 may be arranged under the lower protective layer 1320. The lower pad 1360 may be connected to the through via 1340.

The interposer 1500 may be electrically connected to the package substrate 1200 through conductive bumps 1250 positioned under the lower pad 1360.

In embodiments, the interconnection structure 1400 may be disposed on the substrate 1300 and may include an interlayer insulating layer 1440 and a single-layer or multi-layer wiring structure 1420. When the interconnection structure 1400 includes a multilayer wiring structure, wiring patterns of different layers may be connected to each other through contact vias. An upper pad 1460 electrically connected to the wiring structure 1420 of a single-layer or multi-layer structure may be arranged on the interconnection structure 1400. The semiconductor package 10 and the semiconductor chip 160 may be electrically connected to the upper pad 1460 through the buffer lower solders 521.

In embodiments, the through via 1340 may penetrate the substrate 1300. The through via 1340 may extend into the interior of the interconnection structure 1400 and be electrically connected to the wiring structure 1420 of a single-layer or multi-layer structure of the interconnection structure 1400. When the substrate 1300 includes silicon, the through via 1340 may be referred to as a through silicon via (TSV). In some embodiments, the interposer 1500 may include a redistribution interposer that does not include a through-via, instead of a silicon interposer that includes the through via 1340.

The interposer 1500 may be used to convert or transmit an electric signal between the package substrate 1200, the semiconductor package 10, and the semiconductor chip 160.

The semiconductor chip 160 may include, for example, a central processing unit (CPU), a graphics processing unit (GPU), an FPGA, a digital signal processor (DSP), an encryption processor, a microprocessor, a microcontroller, an analog-to-digital converter, an ASIC, etc. Depending on the type of elements included in the semiconductor chip 160, the semiconductor package 100 may be referred to as a server-oriented semiconductor package or a mobile-oriented semiconductor package.

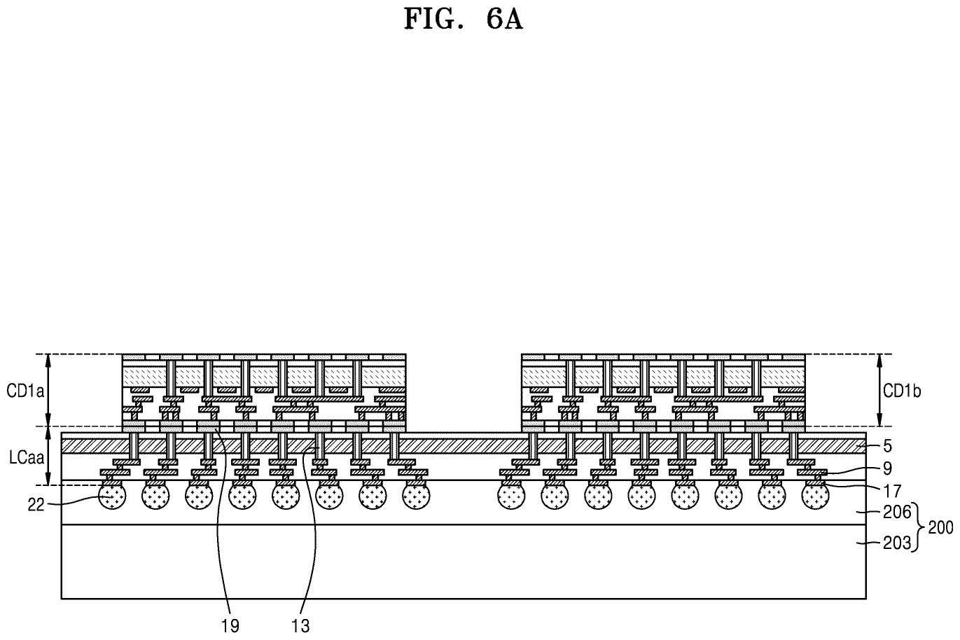

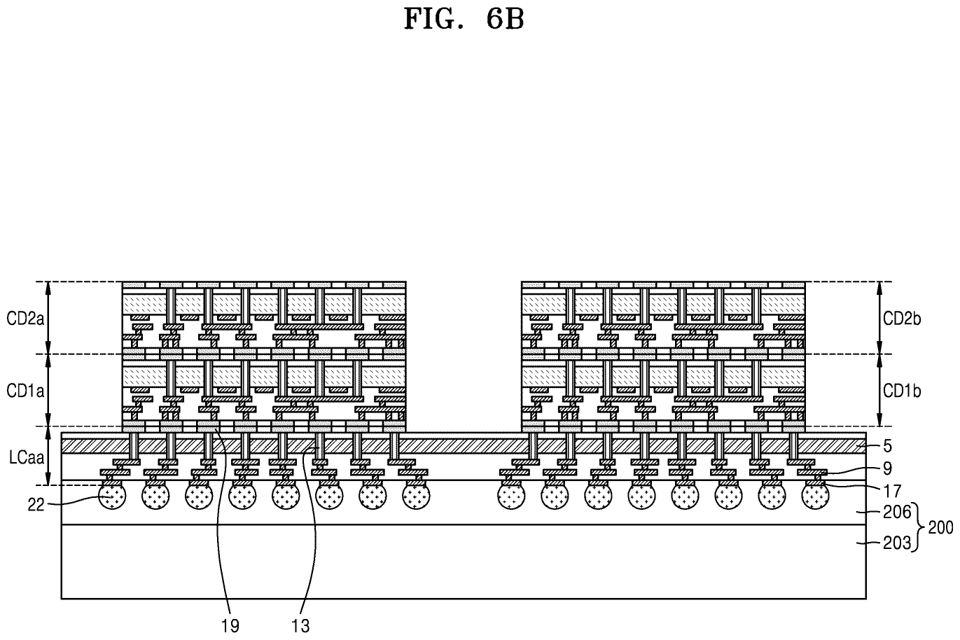

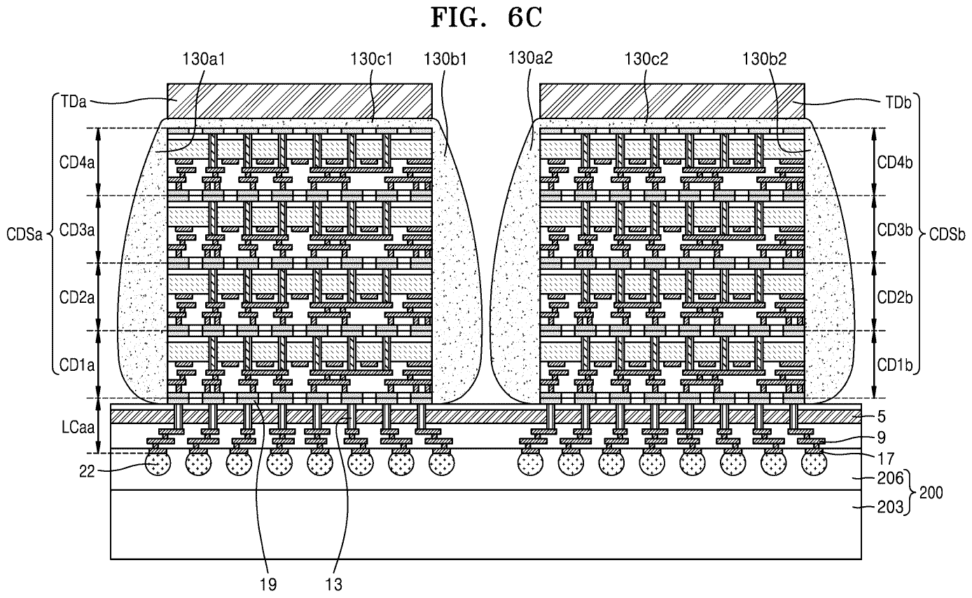

Next, a method of forming a semiconductor package, according to other embodiments, will be described with reference to FIGS. 6A to 6C. FIGS. 6A to 6C are cross-sectional views illustrating parts of a manufacturing method of an embodiment, to explain a semiconductor package according to some embodiments.

Referring to FIG. 6A, first, a base substrate LCaa may be formed. The base substrate LCaa may be arranged on a carrier substrate 200. The carrier substrate 200 may include a support substrate 203 and an adhesive material layer 206 on the support substrate 203.

In embodiments, the base substrate LCaa may include a body portion, a lower pad 17 under the body portion, and an upper pad 19 on the body portion. The body portion may include a substrate 5, wires 9 arranged under the substrate 5, and a through electrode structure 13 penetrating the substrate 5 and electrically connected to the wires 9.

In embodiments, a connection bump 22 may be arranged under the lower pad 17 of the base substrate LCaa. A lower surface of the base substrate LCaa may be bonded to an adhesive material layer 206, and the connection bump 22 may be wrapped by the adhesive material layer 206.

Next, first core dies CD1a and CD1b may be formed on the base substrate LCaa.

Referring to FIG. 6B, second core dies CD2a and CD2b may be respectively formed on the first core dies CD1a and CD1b in the resultant product of FIG. 6A. The bonding between the first core die CD1a and the second core die CD2a and the bonding between the first core die CD1b and the second core die CD2b may be by a hybrid bonding process. That is, the process of bonding the first core dies CD1a and CD1b to the respective second core dies CD2a and CD2b may be the same process as the bonding process between a plurality of core dies included in the core die stack CDS in the semiconductor package 10 or 10a.

In embodiments, the second core dies CD2a and CD2b may have the same structure as the first core dies CD1a and CD1b, but aspects of the inventive concept are not limited thereto.

In FIG. 6B, core dies may be stacked using a hybrid bonding process, adhesive films 130c1 and 130c2 may be arranged between the stacked core dies and the dummy die TD, and then a thermal compression process may be performed to obtain fillets 130a1, 130b1, 130a2, and 130b2 extending down the sidewall of each core die stack CDSa, CDSb. The fillets 130a1, 130b1, 130a2, and 130b2 may at least partially contact an upper surface of the base substrate LCaa. An adhesive film may not be formed between respective core dies of the core die stack CDS.

While aspects of the inventive concept have been particularly shown and described with reference to embodiments thereof, it will be understood that various changes in form and details may be made therein without departing from the spirit and scope of the following claims.

What is claimed is:

1. A semiconductor package comprising:
a buffer die;
a core die stack on the buffer die, the core die stack comprising a plurality of core dies stacked in a vertical direction perpendicular to an upper surface of the buffer die, and including a first sidewall; and
an adhesive film including a first portion and a second portion,
wherein the first portion of the adhesive film is arranged on a lower surface of a top die, the top die being disposed at an uppermost portion of the core die stack,
the second portion of the adhesive film extends in a vertical direction and contacts the first sidewall of the core die stack, and
the second portion of the adhesive film contacts an upper surface of the buffer die.

2. The semiconductor package of claim 1, wherein the adhesive film comprises a non-conductive film (NCF).

3. The semiconductor package of claim 1, wherein the adhesive film is formed of a polymer material.

4. The semiconductor package of claim 1, wherein the top die comprises a dummy die.

5. The semiconductor package of claim 1, wherein the second portion of the adhesive film covers all sidewalls of the core dies positioned between the upper surface of the buffer die and the top die.

6. The semiconductor package of claim 1, wherein a thermal compression bond is formed between the top die and a core die, including in the plurality of core dies, disposed directly below the top die.

7. The semiconductor package of claim 1, wherein each of the plurality of core dies comprises a semiconductor substrate, an internal circuit region disposed under the semiconductor substrate, and a back protective layer disposed on the semiconductor substrate, and further comprises a through electrode structure that extends through the back protective layer and the semiconductor substrate into the internal circuit region.

8. The semiconductor package of claim 7, wherein each of the plurality of core dies comprises a lower bonding pad and a lower bonding insulating layer disposed under a front surface of the semiconductor substrate, and an upper bonding pad and an upper bonding insulating layer disposed over a back surface of the semiconductor substrate.

9. The semiconductor package of claim 8, wherein, between each directly adjacent pairs of the plurality of core dies stacked in the vertical direction,
an upper bonding pad of a lower core die included in a respective adjacent pair of the plurality of core dies is in contact with and bonded to a lower bonding pad of an upper core die include in the respective adjacent pair of the plurality of core dies, and
the upper bonding insulating layer of the lower core die is in contact with and bonded to the lower bonding insulating layer of the upper core die.

10. The semiconductor package of claim 1, further comprising a molding layer that, with respect to a top down view, surrounds the core die stack and the adhesive film,
wherein the adhesive film is formed of a first material, and
the molding layer is formed of a second material that is different from the first material.

11. The semiconductor package of claim 1,
wherein directly adjacent pairs of the plurality of core dies disposed below the top die in in the vertical direction are bonded together with hybrid bonding such that portions of their respective facing surfaces are merged together, and
wherein the top die is bonded to the core die, included in the plurality of core dies, that is directly below the top die in the vertical direction using the adhesive film.

12. The semiconductor package of claim 1, wherein a horizontal cross-sectional area of the buffer die is greater than a horizontal cross-sectional area of the core die stack.

13. A semiconductor package comprising:
a buffer die;
a core die stack on the buffer die, the core die stack comprising first dies stacked in a vertical direction perpendicular to an upper surface of the buffer die to form a stacked structure, and a second die disposed on the stacked structure;
a horizontal portion of an adhesive film, which bonds a top first die, positioned at an uppermost portion of the stacked structure among the first dies, to the second die;
a fillet portion of the adhesive film, the fillet portion extends along a sidewall of the core die stack toward the upper surface of the buffer die, wherein a first end of the fillet portion is integrally connected to the horizontal portion of the adhesive film, and a second end of the fillet portion, opposite to the first end, is in contact with the upper surface of the buffer die; and
a molding layer that covers a top surface of the buffer die and surrounds the core die stack, the horizontal portion of the adhesive film, and the fillet portion of the adhesive film,
wherein the first dies are hybrid bonded to each other.

14. The semiconductor package of claim 13, wherein the horizontal portion of the adhesive film and the fillet portion of the adhesive film comprise a non-conductive film (NCF).

15. The semiconductor package of claim 13, wherein the horizontal portion of the adhesive film and the fillet portion of the adhesive film is formed of a polymer.

16. The semiconductor package of claim 13, wherein bonding between the top first die and the second die is by a thermal compression process using the horizontal portion of the adhesive film as a medium.

17. The semiconductor package of claim 13, wherein a lowermost first die positioned at a lowermost portion among the first dies, the buffer die, and the second end of the fillet portion of the adhesive film are connected to each other.

18. The semiconductor package of claim 13, wherein each of the first dies comprises a semiconductor substrate, an internal circuit region disposed under the semiconductor substrate, and a back protective layer disposed on the semiconductor substrate, and further comprises a through electrode structure that extends through the back protective layer and the semiconductor substrate into the internal circuit region.

19. The semiconductor package of claim 13, wherein a horizontal cross-sectional area of the buffer die is greater than a horizontal cross-sectional area of the core die stack.

20. A semiconductor package comprising:
a buffer die;
core dies disposed on the buffer die and hybrid bonded to each other;
a dummy die arranged on the core dies;
an adhesive film between the core dies and the dummy die;
a fillet connected to an end of the adhesive film and that extends vertically downward along sidewalls of the core dies and contacts the buffer die; and
a molding layer that covers a top surface of the buffer die and surrounds the core dies, the dummy die, the adhesive film, and the fillet,
wherein the dummy die is bonded to the core dies by a thermal compression process,
the fillet is a portion of the adhesive film, which has melted and is hardened through the thermal compression process,
each of the core dies comprises
a semiconductor substrate, an internal circuit region disposed under the semiconductor substrate, a back protective layer disposed on the semiconductor substrate, and a through electrode structure that extends through the back protective layer and the semiconductor substrate into the internal circuit region, and
a core die positioned at a lowermost portion among the core dies, the buffer die, and the fillet are connected to each other.
